(19) United States
(12) Patent Application Publication
(10) Pub. No.: US 2006/0280220 A1
(43) Pub. Date: Dec. 14, 2006

(54) Optically-pumped vertical external cavity surface emitting laser

(75) Inventor: Jae-ryung Yoo, Suwon-si (KR)

Correspondence Address: BUCHANAN, INGERSOLL & ROONEY PC, POST OFFICE BOX 1404, ALEXANDRIA, VA, 22313-1404, US

(73) Assignee: Samsung Electronics Co., Ltd., Suwon-si (KR)

(21) Appl. No.: 11/431,666

(22) Filed: May 11, 2006

(30) Foreign Application Priority Data
Jun. 8, 2005 (KR) 10-2005-0048859

(51) Int. Cl. H01S 3/04; H01S 3/10; H01S 5/00; H01S 3/091; H01S 3/08; H01S 3/092

(52) U.S. Cl. 372/99; 372/50.11; 372/70; 372/22; 372/36

(57) ABSTRACT

A vertical external cavity surface emitting laser (VECSEL) is provided in which a pump laser beam is incident on a laser chip at a right angle. In the surface emitting laser, a laser chip emits light at a first wavelength by optical pumping, an external mirror is spaced apart from the laser chip to reflect the first wavelength light emitted from the laser chip back to the laser chip, a pump laser emits light at a second wavelength to cause the laser chip to lase, a wavelength selecting mirror is disposed between the laser chip and the external mirror to reflect the second wavelength light emitted from pump laser to the laser chip and to transmit the first wavelength light emitted from the laser chip, and an optical unit is disposed between the wavelength selecting mirror and the laser chip to focus the first wavelength light on an optical path between the external mirror and the wavelength selecting mirror and to focus the second wavelength light on the laser chip.

### CROSS-REFERENCE TO RELATED PATENT APPLICATION

This application claims the benefit of Korean Patent Application No. 10-2005-0048859, filed on Jun. 8, 2005, in the Korean Intellectual Property Office, the disclosure of which is incorporated herein in its entirety by reference.

### BACKGROUND OF THE DISCLOSURE

1. Field of the Disclosure

The present disclosure relates to an optically-pumped surface emitting laser, and more particularly, to a vertical external cavity surface emitting laser (VECSEL) in which a pump laser beam is incident on a laser chip at a right angle.

2. Description of the Related Art

A VECSEL is a laser device that has a gain region increased by replacing an upper mirror of a vertical cavity surface emitting laser (VCSEL) with an external mirror to obtain a high output power in the range of several to several tens of wafts or more.

FIG. 1 is a schematic sectional view of a conventional optically-pumped VECSEL. Referring to FIG. 1, a conventional optically-pumped VECSEL 10 includes a laser chip 13 for laser oscillation, a heat spreader 12, a heat sink 11 to which the laser chip 13 is attached through the heat spreader 12, and an external mirror 16 spaced apart from the laser chip 13. The VECSEL 10 further includes a pump laser 14 disposed at an angle to provide a pump beam to the laser chip 13. The laser chip 13 includes a distributed Bragg reflector (DBR) layer 13a and an active layer 13b that are sequentially stacked. The active layer 13b, for example, has a multi quantum well structure and is excited by a pump beam to emit light at a predetermined wavelength. The pump laser 14 emits light at a wavelength shorter than the oscillation wavelength of the laser chip 13, and the light emitted from the pump laser 14 is directed to the laser chip 13 through a lens 15 to excite the active layer 13b of the laser chip 13.

Further, a filter 17, which passes light only at a specific wavelength, and a second harmonic generation (SHG) crystal 18, which doubles the frequency of light, may be additionally disposed between the laser chip 13 and the external mirror 16. If the SHG crystal 18 is used, for example, infrared light emitted from the laser chip 13 can be converted into visible light.

In this structure, when light emitted from the pump laser 14 is incident on the laser chip 13 through the lens 15, the activating layer 13b in the laser chip 13 is excited to generate light at a specific wavelength. The light generated from the active layer 13b is repeatedly reflected between the DBR layer 13a and the external mirror 16 through the active layer 13b. The light is amplified in the active layer 13b through this repeated reflection, and a portion of the amplified light is outputted to the outside through the external mirror 16 as a laser beam.

However, according to the aforementioned conventional VECSEL 10, the pump laser 14 used for activating of the laser chip 13 is diagonally disposed, thereby making it difficult to align the entire components of the VECSEL 10. Further, an aperture defined in a top portion of the heat sink 11 must be sufficiently large to prevent the pump beam from being blocked by the heat sink 11. This increases the size of the heat spread 12 and thereby increases the manufacturing cost. Furthermore, since the pump beam emitted from the pump laser 14 is incident on the laser chip 13 at an inclined angle, the oscillation efficiency of the laser chip 13 decreases.

Meanwhile, the optical wavelength converting efficiency of the SHG crystal 18 is proportional to the intensity of incident light, and as shown in FIG. 2, the radius of a beam increases as it passes away from the laser chip 13. Therefore, it is preferable that the SHG crystal 18 is disposed close to the laser chip 13. However, the SHG crystal 18 cannot be disposed close to the laser chip 13 because of the filter 17 and the pump laser 14, thereby decreasing the efficiency of the SHG crystal 18.

FIG. 3 is a schematic diagram of a conventional VECSEL that is designed to increase the efficiency of the SHG crystal. Referring to FIG. 3, in a conventional VECSEL 20, light generated from a laser chip 21 passes through a filter 23 and is reflected by a first external mirror 24 to a second external mirror 25. The light is reflected by the second mirror 25, and then the light is incident on the laser chip 21 via the first external mirror 24. A SHG crystal 26 is disposed between the first and second external mirrors 24 and 25, and light wavelength-converted by the SHG crystal 26 is outputted to the outside through the first external mirror 24. Here, by forming both the first and second external mirrors 24 and 25 as concave mirrors, the efficiency of the SHG crystal 26 can be increased because light is converged on the SHG crystal 26.

However, the conventional VECSEL 20 requires an additional external mirror, and also it is difficult to align the two external mirrors because the external mirrors must be diagonally arranged. Therefore, the overall size of the laser system becomes larger. Further, the VECSEL 20 has another disadvantage of outputting a laser beam at an angle. In addition, the aforementioned problems resulting from diagonal arrangement of a pump laser 22 and a lens 27 are not resolved.

### SUMMARY OF THE DISCLOSURE

The present invention provides a VECSEL that is designed to make a pump laser beam incident a laser chip at a right angle to increase oscillation efficiency and allow easy alignment.

The present invention also provides a VECSEL that is designed to focus a light beam generated from a laser chip onto an SHG crystal to increase the optical converting efficiency of the SHG crystal.

According to an aspect of the present invention, there is provided a surface emitting laser including: a laser chip emitting light at a first wavelength by optical pumping; an external mirror spaced apart from the laser chip to reflect the first wavelength light emitted from the laser chip back to the laser chip; a pump laser emitting light at a second wavelength to activate the laser chip; a wavelength selective mirror disposed between the laser chip and the external mirror to reflect the second wavelength light emitted from pump laser to the laser chip and to transmit the first wavelength light emitted from the laser chip; and an optical element disposed between the wavelength selective mirror and the laser chip to focus the first wavelength light on an optical path between the external mirror and the wavelength selective mirror and to focus the second wavelength light on the laser chip.

The surface emitting laser may further include an SHG crystal disposed between the external mirror and the wavelength selective mirror at a position on which the first wavelength light is focused to double the frequency of the first wavelength light to convert the first wavelength light into a third wavelength light.

The wavelength selective mirror may be a double refraction filter transmitting only the first wavelength light, and a laser chip side surface of the wavelength selective mirror may be formed with a coating layer having an anti-reflection characteristic for the first wavelength light and a reflection characteristic for the second wavelength light.

According to an embodiment of the present invention, an SHG crystal side surface of the wavelength selective mirror may be formed with a coating layer having an anti-reflection characteristic for the first wavelength light and a reflection characteristic for the third wavelength light to output the third wavelength light to an outside in a direction perpendicular to the optical path.

Both side surfaces of the SHG crystal may be formed with coating layers having an anti-reflection characteristic for both the first wavelength light and the third wavelength light.

The external mirror may include a concave reflecting surface formed with a coating layer having a reflection characteristic for both the first wavelength light and the third wavelength light.

According to another embodiment of the present invention, an SHG crystal side surface of the wavelength selective mirror may be formed with a coating layer having an anti-reflection characteristic for the first wavelength light.

A wavelength selective mirror side surface of the SHG crystal may be formed with a coating layer having an anti-reflection characteristic for the first wavelength light and a reflection characteristic for the third wavelength light, and an external mirror side surface of the SHG crystal may be formed with a coating layer having an anti-reflection characteristic for both the first wavelength light and the third wavelength light.

The external mirror may include a concave reflecting surface formed with a coating layer having a reflection characteristic for the first wavelength light and an anti-reflection characteristic for the third wavelength light to output the third wavelength light to an outside through the external mirror.

According to a further another embodiment of the present invention, the wavelength selective mirror may be a beam splitter including a laser chip side surface formed with a coating layer having an anti-reflection characteristic for the first wavelength light and a reflection characteristic for the second wavelength light. In this case, the external mirror may include a flat reflecting surface formed with a coating layer to transmit a portion of the first wavelength light to an outside and to reflect the remaining portion toward the laser chip.

Meanwhile, the surface emitting laser of the present invention may further include a heat sink disposed on a bottom surface of the laser chip to dissipate heat generated from the laser chip. The surface emitting laser of the present invention may further include a heat spreader disposed on a top surface of the laser chip to transfer the heat generated from the laser chip to the heat sink.

### BRIEF DESCRIPTION OF THE DRAWINGS

The above and other features and advantages of the present invention will be described in detailed exemplary embodiments thereof with reference to the attached drawings in which:

FIG. 1 is a sectional view of a conventional optically-pumped VECSEL;

FIG. 2 is a graph showing variation of beam radius in a cavity of a conventional VECSEL;

FIG. 3 is a sectional view of another conventional VECSEL;

FIG. 4 is a sectional view of a VECSEL according to an embodiment of the present invention;

FIG. 5 is a graph showing variation of beam radius in a cavity of a VECSEL according to the present invention;

FIG. 6 is a sectional view of a VECSEL according to another embodiment of the present invention; and

FIG. 7 is a sectional view of a VECSEL according to a further another embodiment of the present invention.

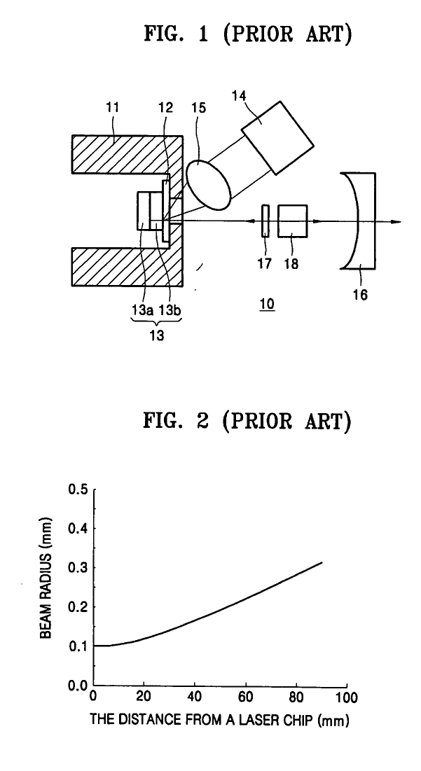

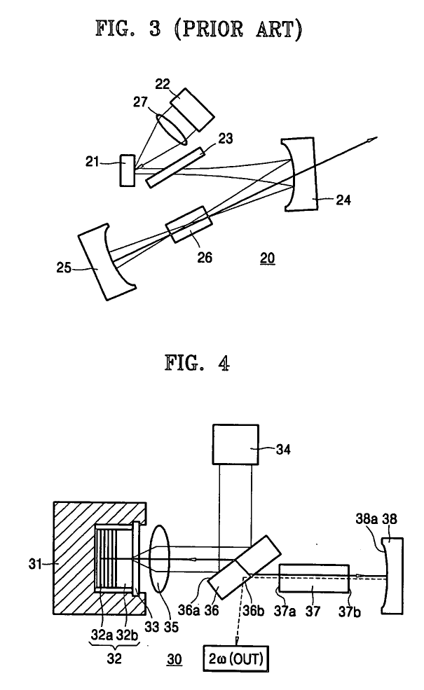

### DETAILED DESCRIPTION OF PREFERED EMBODIMENTS

FIG. 4 is a sectional view of a VECSEL according to an embodiment of the present invention. Referring to FIG. 4, a laser chip 32 may be loaded on a heat sink 31, and a transparent heat spreader 33 may be disposed on the laser chip 32. The heat spreader 33 transfers heat generated from the laser chip 32 to the heat sink 31 to dissipate the heat to the outside, and for this purpose, the heat spreader 33 is formed of material having a high optical transmittance and thermal conductivity such as diamond. In a VECSEL 30 of an embodiment of the present invention, the laser chip 32 is activated by optical pumping to emit light at a first wavelength. As known to those of ordinary skill in the art, the laser chip 32 includes a DBR layer 32a and an active layer 32b that are sequentially stacked. The active layer 32b, for example, has a multi quantum well structure, and it is exited by pump light to emit light at a predetermined wavelength.

An external mirror 38 is spaced apart from the laser chip 32 while confronting the laser chip 32. The external mirror 38 reflects the first wavelength light emitted from the laser chip 32 back to the laser chip 32. Preferably, the external mirror 38 includes a concave reflecting surface 38a to converge the reflecting light.

A pump laser 34 emits light at a second wavelength to activate the laser chip 32. The pump laser 34 is disposed substantially perpendicular to the optical path of the first wavelength light emitted from the laser chip 32. Generally, the oscillation wavelength of the pump laser 34 is shorter than that of the laser chip 32. For example, if the wavelength of the light emitted from the laser chip 32 is 1064 nm (i.e., if the first wavelength is 1064 nm), the wavelength of the light emitted from the pump laser 34 is properly about 808 nm (i.e., the second wavelength is about 808 nm).

Unlike the related art in which pump light emitted from a pump laser is directly incident on a laser chip, in the VECSEL 30 of the present invention, the pump light is incident on the laser chip 32 through a wavelength selective mirror 36. As shown in FIG. 4, the wavelength selective mirror 36 is disposed between the laser chip 32 and the external mirror 38 while confronting the pump laser 34 disposed at a side in a vertical direction. The wavelength selective mirror 36 reflects the second wavelength light emitted from the pump laser 34 toward the laser chip 32 and transmits the first wavelength light emitted from the laser chip 32. For example, a coating layer, which has an anti-reflection characteristic with respect to the first wavelength light and a reflection characteristic with respect to the second wavelength light, can be formed on glass to form the wavelength selective mirror 36. More preferably, instead of the glass, a double refraction filter transmitting only the first wavelength light can be used to make the wavelength selective mirror 36. Generally, since the light emitted from the laser chip 32 has a relatively wide spectrum band with the first wavelength as a center wavelength, it is necessary to select only the first wavelength light or at least narrow the spectrum band by using the double refraction filter to increase the quality of laser beam output.

Further, an optical element 35 is disposed across an optical path between the laser chip 32 and the wavelength selective mirror 36 to focus the second wavelength pump light emitted from the pump laser 34 onto the laser chip 32. For example, a convex lens can be used for the optical element 35, or another type optical unit such as a lens group with a plurality of lenses can be used for the optical element 35. Further, the optical element 35 focuses the first wavelength light emitted from the laser chip 32 on an optical path between the external mirror 38 and the wavelength selective mirror 36. In this instance, the beam radius of the first wavelength light emitted from the laser chip 32 varies as shown in FIG. 5. That is, since the light emitted from the laser chip 32 is divergent in some degree, the beam radius gradually increases. However, the light is converged by the optical element 35, and thus the beam radius becomes smallest at a predetermined position between the wavelength selective mirror 36 and the external mirror 38.

As shown in FIGS. 4 and 5, an SHG crystal 37 can be disposed between the wavelength selective mirror 36 and the external mirror 38 at the predetermined position where the beam radius of the first wavelength light emitted from the laser chip 32 is minimum. As described above, the SHG crystal 37 converts the first wavelength light emitted from the laser chip 32 into a third wavelength light by doubling the frequency of the first wavelength light. For example, if the wavelength of the light emitted from the laser chip 32 is 1064 nm (i.e., if the first wavelength is 1064 nm), the wavelength of the light converted by the SHG crystal 37 is 532 nm (i.e., the third wavelength is 532 nm). Therefore, if the SHG crystal 37 is used, light in the infrared wavelength region can be outputted after being converted into light in the visible wavelength region. Generally, the optical wavelength converting efficiency of the SHG crystal 37 is proportional to the energy density of incident light. Therefore, in the embodiment of the present invention, the SHG crystal 37 is placed at the predetermined position where the beam radius of the first wavelength light is smallest, thereby optimizing the optical wavelength converting efficiency of the SHG crystal 37.

Meanwhile, according to the embodiment of the present invention, proper coating layers are respectively formed on surfaces of the wavelength selective mirror 36, the SHG crystal 37, and the external mirror 38, such that the first wavelength light emitted from the laser chip 32, the second wavelength light emitted from the pump laser 34, and the third wavelength light converted by the SHG crystal 37 can travel along predetermined optical paths, respectively. For example, a laser chip side surface 36a of the wavelength selective mirror 36 may be formed with a coating layer that has an anti-reflection (AR) characteristic with respect to the first wavelength light and a high-reflection (HR) characteristic with respect to the second wavelength light, and an SHG crystal side surface 36b of the wavelength selective mirror 36 may be formed with a coating layer that has an AR characteristic with respect to the first wavelength light and an HR characteristic with respect to the third wavelength light. Further, both side surfaces 37a and 37b of the SHG crystal 37 may be formed with coating layers that have an AR characteristic with respect to both the first wavelength light and the third wavelength light, and the concave reflecting surface 38a of the external mirror 38 may be formed with a coating layer that has an HR characteristic with respect to both the first wavelength light and the third wavelength light. These coating layers may be formed by stacking a plurality of materials having different refractive indice, and desired optical characteristics (e.g., wavelength of reflected light, wavelength of transmitted light, reflectance, and transmittance) can be readily obtained by properly selecting the kind, thickness, etc. of the stacking material according to well-know parameters.

In the aforementioned VECSEL 30, the second wavelength light emitted from the pump laser 34 is reflected by the wavelength selective mirror 36 and focused on the laser chip 32 through the optical element 35. The active layer 32b of the laser chip 32 is excited to emit the first wavelength light. Through the optical element 35 and the wavelength selective mirror 36, the first wavelength light emitted from the laser chip 32 is incident on the SHG crystal 37 where the first wavelength light is converted into the third wavelength light having half the wavelength of the first wavelength light. Here, since all the first wavelength light is not converted into the third wavelength light, light from the SHG crystal 37 has both the first wavelength and the third wavelength. The first and third wavelength light is reflected by the external mirror 38 back to the SHG crystal 37 where a portion of the first wavelength light is converted into the third wavelength light. Thereafter, the first and third wavelength light exits the SHG crystal 37 and is incident on the wavelength selective mirror 36. As described above, the SHG crystal side surface 36b of the wavelength selective mirror 36 transmits the first wavelength light and reflects the third wavelength light. Therefore, the third wavelength light is reflected by the wavelength selective mirror 36 in a lateral direction such that the third wavelength light can be outputted to the outside as a laser beam. Further, the first wavelength light is transmitted through the wavelength selective mirror 36 to the laser chip 32 where the first wavelength light is reflected by the DBR layer 32a back to the external mirror 38.

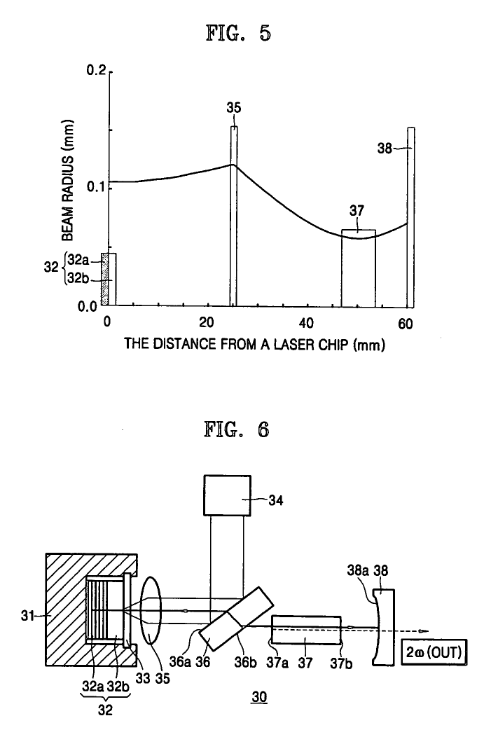

FIG. 6 is a sectional view of a VECSEL according to another embodiment of the present invention. Referring to FIG. 6, the VECSEL of the another embodiment of the present invention has the same structure as the VECSEL shown in FIG. 4, except that the optical characteristics of the coating layers are changed to output a laser beam to the outside through an external mirror. That is, a heat sink 31, a laser chip 32, a heat spreader 33, a laser pump 34, an optical unit 35, a wavelength selective mirror 36, an SHG crystal 37, and an external mirror 38 are constructed and arranged in the same way as the VECSEL described with reference to FIG. 4.

For example, in the VECSEL of FIG. 6, a laser chip side surface 36a of the wavelength selective mirror 36 may be formed with a coating layer that has an AR characteristic with respect to first wavelength light and an HR characteristic with respect to second wavelength light, and an SHG crystal side surface 36b of the wavelength selective mirror 36 may be formed with a coating layer that has an AR characteristic with respect to the first wavelength light. Further, a wavelength selective mirror side surface 37a of the SHG crystal 37 is formed with a coating layer that has an AR characteristic with respect to the first wavelength light and an HR characteristic with respect to third wavelength light, and an external mirror side surface 37b of the SHG crystal 37 is formed with a coating layer that has an AR characteristic with respect to both the first wavelength light and the third wavelength light. Furthermore, a concave reflecting surface 38a of the external mirror 38 is formed with a coating layer that has an HR characteristic with respect to the first wavelength light and an AR characteristic with respect to the third wavelength light.

In the VECSEL of FIG. 6, the second wavelength light emitted from the pump laser 34 is reflected by the wavelength selective mirror 36 and is focused on the laser chip 32 through the optical element 35. Upon this, the active layer 32b of the laser chip 32 is excited to emit the first wavelength light. Through the optical element 35 and the wavelength selective mirror 36, the first wavelength light emitted from the laser chip 32 is incident on the SHG crystal 37 where the first wavelength light is converted into the third wavelength light having half the wavelength of the first wavelength light. As described above, since all the first wavelength light is not converted into the third wavelength light, light from the SHG crystal 37 has both the first wavelength and the third wavelength. Thereafter, the first and third wavelength light from the SHG crystal 37 is incident on the external mirror 38. Owing to the coating layer formed on the reflecting surface 38a of the external mirror 38, the reflecting surface 38a has a highly reflection characteristic for the first wavelength light and a transmitting characteristic for the third wavelength light. Therefore, the first wavelength light is reflected back to the SHG crystal 37, and the third wavelength light is outputted to the outside as a laser beam. A portion of the first wavelength light reflected back to the SHG crystal 37 is converted into the third wavelength light. Meanwhile, the wavelength selective mirror side surface 37a of the SHG crystal 37 is formed with the coating layer having an AR characteristic for the first wavelength light and an HR characteristic for the third wavelength light. Therefore, the first wavelength light is transmitted through the SHG crystal 37 and the wavelength selective mirror 36 to the laser chip 32, and the third wavelength light is reflected by the wavelength selective mirror side surface 37a of the SHG crystal 37 to the external mirror 38 where the third wavelength light is outputted to the outside.

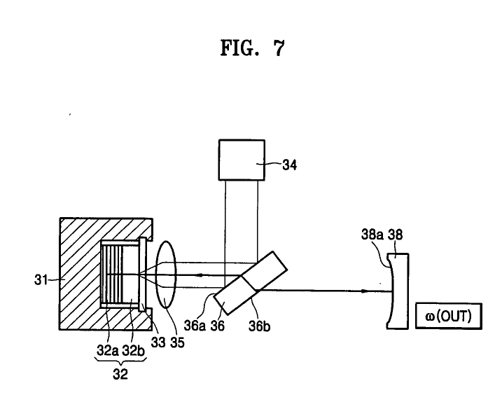

FIG. 7 is a sectional view of a VECSEL according to a further another embodiment of the present invention. When compared with the VECSELs of the aforementioned embodiments, the VECSEL shown in FIG. 7 does not use the SHG crystal but other structures thereof are the same as the aforementioned VECSELs. Since the VECSEL shown in FIG. 7 does not use the SHG crystal, it is not necessary to converge light on the SHG crystal. Therefore, a reflecting surface 38a of an external mirror 38 can have a flat shape. Further, first wavelength light generated from a laser chip 32 is outputted to the outside as a laser beam without change. For this, it is preferable that the reflecting surface 38a of the external mirror 38 is formed with a coating layer that can transmit a portion of the first wavelength light to the outside and reflect the remaining portion to the laser chip 32. Further, a wavelength selective mirror 36 can be made of a beam splitter formed with a coating layer having an AR characteristic for the first wavelength light and a reflection characteristic for a second wavelength light.

As described above, the surface emitting laser of the embodiments of the present invention, particularly the VECSEL uses a wavelength selective mirror to project the pump light to the laser chip in a perpendicular direction, so that a high oscillation efficiency can be attained and a small heat spreader can be used. Further, components of the VECSEL can be easily arranged since the pump layer is not required to be precisely aligned with the laser chip. Therefore, the manufacturing cost and overall size of the laser device can be reduced.

In addition, according to embodiments of the present invention, the light generated from the laser chip can be simply focused on the SHG crystal, thereby optimizing the optical converting efficiency of the SHG crystal.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A surface emitting laser comprising:
a laser chip emitting light at a first wavelength by optical pumping;
an external mirror spaced apart from the laser chip to reflect the first wavelength light emitted from the laser chip back to the laser chip;
a pump laser emitting light at a second wavelength to activate the laser chip;
a wavelength selective mirror disposed between the laser chip and the external mirror to reflect the second wavelength light emitted from pump laser to the laser chip and to transmit the first wavelength light emitted from the laser chip; and
an optical element disposed between the wavelength selective mirror and the laser chip to focus the first wavelength light on an optical path between the external mirror and the wavelength selective mirror and to focus the second wavelength light on the laser chip.

2. The surface emitting laser of claim 1, further comprising an SHG (second harmonic generation) crystal disposed between the external mirror and the wavelength selective mirror at a position on which the first wavelength light is focused to double the frequency of the first wavelength light to convert the first wavelength light into a third wavelength light.

3. The surface emitting laser of claim 2, wherein the wavelength selective mirror is a double refraction filter transmitting only the first wavelength light, and a laser chip side surface of the wavelength selective mirror is formed with a coating layer having an anti-reflection characteristic for the first wavelength light and a reflection characteristic for the second wavelength light.

4. The surface emitting laser of claim 3, wherein an SHG crystal side surface of the wavelength selective mirror is formed with a coating layer having an anti-reflection characteristic for the first wavelength light and a reflection characteristic for the third wavelength light to output the third wavelength light to the outside in a direction perpendicular to the optical path.

5. The surface emitting laser of claim 4, wherein both side surfaces of the SHG crystal are formed with coating layers having an anti-reflection characteristic for both the first wavelength light and the third wavelength light.

6. The surface emitting laser of claim 5, wherein the external mirror includes a concave reflecting surface formed with a coating layer having a reflection characteristic for both the first wavelength light and the third wavelength light.

7. The surface emitting laser of claim 3, wherein an SHG crystal side surface of the wavelength selective mirror is formed with a coating layer having an anti-reflection characteristic for the first wavelength light.

8. The surface emitting laser of claim 7, wherein a wavelength selective mirror side surface of the SHG crystal is formed with a coating layer having an anti-reflection characteristic for the first wavelength light and a reflection characteristic for the third wavelength light, and an external mirror side surface of the SHG crystal is formed with a coating layer having an anti-reflection characteristic for both the first wavelength light and the third wavelength light.

9. The surface emitting laser of claim 8, wherein the external mirror includes a concave reflecting surface formed with a coating layer having a reflection characteristic for the first wavelength light and an anti-reflection characteristic for the third wavelength light to output the third wavelength light to the outside through the external mirror.

10. The surface emitting laser of claim 1, wherein the wavelength selective mirror is a beam splitter including a laser chip side surface formed with a coating layer having an anti-reflection characteristic for the first wavelength light and a reflection characteristic for the second wavelength light.

11. The surface emitting laser of claim 10, wherein the external mirror includes a flat reflecting surface formed with a coating layer to transmit a portion of the first wavelength light to the outside and to reflect the remaining portion toward the laser chip.

12. The surface emitting laser of claim 1, further comprising a heat sink disposed on a bottom surface of the laser chip to dissipate heat generated from the laser chip.

13. The surface emitting laser of claim 12, further comprising a heat spreader disposed on a top surface of the laser chip to transfer the heat generated from the laser chip to the heat sink.
